(19) United States
(12) Patent Application Publication
(10) Pub. No.: US 2020/0371563 A1
(43) Pub. Date: Nov. 26, 2020

(54) ELECTRONIC DEVICE WITH MULTIPLE HINGES

(71) Applicant: Intel Corporation, Santa Clara, CA (US)

(72) Inventors: David M. Collins, Portland, OR (US); Brett True Branch, Molalla, OR (US); Shashi R. Karpur, Chandler, AZ (US); Samarth Alva, Bangalore (IN); Yogesh Channaiah, Karnataka (IN)

(73) Assignee: Intel Corporation, Santa Clara, CA (US)

(21) Appl. No.: 16/988,851

(22) Filed: Aug. 10, 2020

(51) Int. Cl. G06F 1/16; H05K 5/02; H05K 7/16

(52) U.S. Cl. CPC G06F 1/1681; H05K 7/16; H05K 5/0226

(57) ABSTRACT

Particular embodiments described herein provide for an electronic device that can be configured to include a first housing, a second housing, a carrier plate, and a base. A first hinge can rotatably couple the first housing to the second housing and a carrier plate to the first housing and to the second housing. A second hinge can rotatably couple the carrier plate to the base.

### TECHNICAL FIELD

This disclosure relates in general to the field of computing, and more particularly, to an electronic device with multiple hinges.

### BACKGROUND

End users have more electronic device choices than ever before. A number of prominent technological trends are currently afoot and these trends are changing the electronic device landscape. Some of the technological trends involve laptop computers and clamshell devices. Generally, clamshell devices are devices where a first housing is rotatably coupled to a second housing. For example, a laptop, notebook computer, etc., is a small, portable personal computer with a clamshell form factor typically having a computer display mounted on the inside of an upper first housing of the clamshell and an alphanumeric keyboard on the inside of a lower second housing of the clamshell. The clamshell device is opened to use the device and Folded shut for transportation or storage.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1 is a simplified block diagram of a system to enable an electronic device with multiple hinges, in accordance with an embodiment of the present disclosure;

FIG. 2 is a simplified block diagram of a system to enable an electronic device with multiple hinges, in accordance with an embodiment of the present disclosure;

FIG. 3 is a simplified block diagram of a system to enable an electronic device with multiple hinges, in accordance with an embodiment of the present disclosure;

FIG. 4 is a simplified block diagram of a system to enable an electronic device with multiple hinges, in accordance with an embodiment of the present disclosure;

FIG. 5 is a simplified block diagram of a system to enable an electronic device with multiple hinges, in accordance with an embodiment of the present disclosure;

FIG. 6 is a simplified block diagram of a system to enable an electronic device with multiple hinges, in accordance with an embodiment of the present disclosure;

FIG. 7 is a simplified block diagram of a system to enable an electronic device with multiple hinges, in accordance with an embodiment of the present disclosure;

FIG. 8 is a simplified block diagram of a system to enable an electronic device with multiple hinges, in accordance with an embodiment of the present disclosure;

FIG. 9 is a simplified block diagram of a system to enable an electronic device with multiple hinges, in accordance with an embodiment of the present disclosure;

FIG. 10 is a simplified block diagram of a system to enable an electronic device with multiple hinges, in accordance with an embodiment of the present disclosure;

FIG. 11 is a simplified block diagram of a system to enable an electronic device with multiple hinges, in accordance with an embodiment of the present disclosure;

FIG. 12 is a simplified block diagram of a system to enable an electronic device with multiple hinges, in accordance with an embodiment of the present disclosure;

FIG. 13 is a simplified block diagram of a system to enable an electronic device with multiple hinges, in accordance with an embodiment of the present disclosure;

FIG. 14 is a simplified block diagram of a system to enable an electronic device with multiple hinges, in accordance with an embodiment of the present disclosure;

FIG. 15 is a simplified block diagram of a system to enable an electronic device with multiple hinges, in accordance with an embodiment of the present disclosure;

FIG. 16 is a simplified block diagram of a system to enable an electronic device with multiple hinges, in accordance with an embodiment of the present disclosure;

FIG. 17 is a simplified block diagram of a system to enable an electronic device with multiple hinges, in accordance with an embodiment of the present disclosure;

FIG. 18 is a simplified block diagram of a portion of a system to enable an electronic device with multiple hinges, in accordance with an embodiment of the present disclosure;

FIG. 19 is a simplified block diagram of a system to enable an electronic device with multiple hinges, in accordance with an embodiment of the present disclosure;

FIG. 20 is a simplified block diagram of a portion of a system to enable an electronic device with multiple hinges, in accordance with an embodiment of the present disclosure;

FIG. 21 is a simplified block diagram of a portion of a system to enable an electronic device with multiple hinges, in accordance with an embodiment of the present disclosure; and

FIG. 22 is a simplified block diagram of an electronic device with multiple hinges, in accordance with an embodiment of the present disclosure.

The FIGURES of the drawings are not necessarily drawn to scale, as their dimensions can be varied considerably without departing from the scope of the present disclosure.

### DETAILED DESCRIPTION

### EXAMPLE EMBODIMENTS

The following detailed description sets forth examples of devices, apparatuses, methods, and systems relating to an electronic device with multiple hinges. Features such as structure(s), function(s), and/or characteristic(s), for example, are described with reference to one embodiment as a matter of convenience; various embodiments may be implemented with any suitable one or more of the described features.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

The terms “over,” “under,” “below,” “between,” and “on” as used herein refer to a relative position of one layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “directly on” a second layer is in direct contact with that second layer. Similarly, unless explicitly stated otherwise, one feature disposed between two features may be in direct contact with the adjacent features or may have one or more intervening layers.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

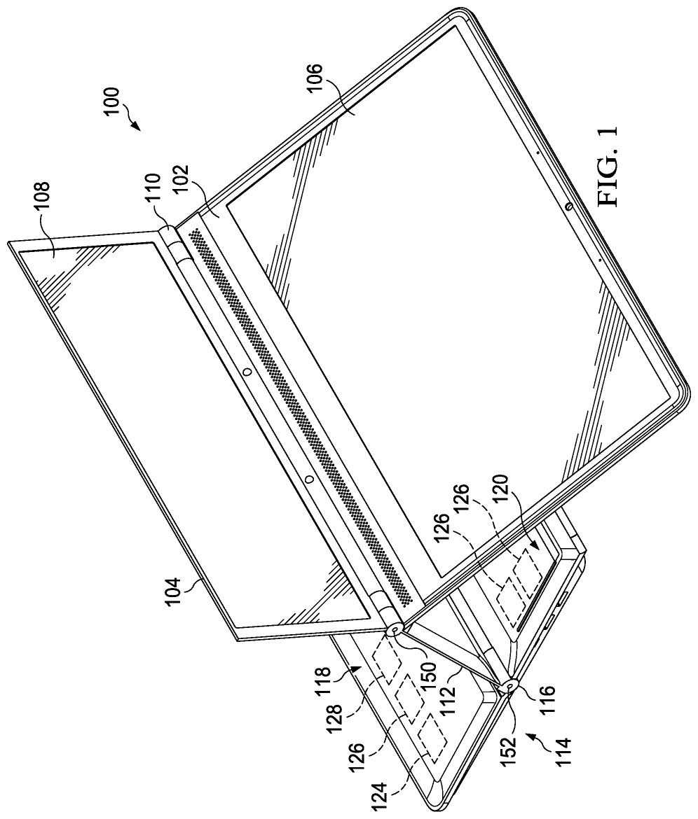

FIG. 1 is a simplified block diagram of an electronic device 100 configured to enable an electronic device with multiple hinges. Electronic device 100 can include a first housing 102 and a second housing 104. First housing 102 can include a first housing display 106 and second housing 104 can include a second housing display 108. First housing can be rotatably coupled to second housing 104 using a first hinge 110. First hinge 110 can include a first hinge retention mechanism 150. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints. First housing display 106 and second housing display 108 can each be a liquid crystal display (LCD) display screen, a light-emitting diode (LED) display screen, an organic light-emitting diode (OLED) display screen, a plasma display screen, touchscreen, or any other suitable display screen system.

As illustrated in FIG. 1, a carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. A base housing 114 can be rotatably coupled to carrier plate 112 using second hinge 116. In an example, carrier plate 112 can be rotated on second hinge 116 about one hundred and eighty degrees (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints.

In an example, first housing 102 can be rotated on first hinge 110 about one hundred and eighty degrees (180°) relative to base housing 114. In another example, first housing 102 can be rotated on first hinge 110 about three hundred and sixty degrees (360°) relative to base housing 114. In yet other examples, first housing 102 can be rotated on first hinge 110 about two hundred and seventy degrees (270°) relative to base housing 114 or some other angle, depending on design constraints. First hinge 110 can include a first hinge retention mechanism 150. Second hinge 116 can include a second hinge retention mechanism 152. First hinge retention mechanism 150 may be a torque hinge, friction hinge, clutch hinge or some other type of retention mechanism that can hold first housing 102, second housing 104, and carrier plate 112 in a set display position. For example, a user can position first housing 102, second housing 104, and carrier plate 112 in a desired location or configuration and first hinge retention mechanism 150 can keep first housing 102, second housing 104, and carrier plate 112 in the desired location or configuration set by the user. Second hinge retention mechanism 152 may be a torque hinge, friction hinge, clutch hinge or some other type of retention mechanism that can hold carrier plate 112 in a set base position relative to base housing 114. For example, a user can position carrier plate 112 in a desired location or configuration and second hinge retention mechanism 152 can keep carrier plate 112 in the desired location or configuration set by the user.

Base housing 114 can include a first base housing portion 118 and a second base housing portion 120. Base housing 114 can include one or more processors 124, memory 126, and electronics 128. Each of electronics 128 can be a device or group of devices available to assist in the operation or function of electronic device 100.

It is to be understood that other embodiments may be utilized and structural changes may be made without departing from the scope of the present disclosure. Substantial flexibility is provided by electronic device 100 in that any suitable arrangements and configuration may be provided without departing from the teachings of the present disclosure.

For purposes of illustrating certain example techniques of electronic device 100, the following foundational information may be viewed as a basis from which the present disclosure may be properly explained. Generally, clamshell devices are devices where a first housing is rotatably coupled to a second housing. For example, a clamshell device can be a laptop, notebook computer or other a small, portable personal computer with a clamshell form factor typically having a computer display mounted on the inside of an upper first housing of the clamshell and an alphanumeric keyboard on the inside of a lower second housing of the clamshell. The clamshell is opened to use the device and folded shut for transportation or storage. Some users use the electronic device for gaming, graphic arts, high performance usage, etc. and prefer to use two screens. However, using two screens in a portable device can create problems.

A device with multiple hinges, as outlined in FIG. 1, can resolve these issues (and others). In an example implementation, electronic device 100 is meant to encompass a computer, a laptop or electronic notebook, mobile device, or any other device that includes multiple hinges and multiple displays. Electronic device 100 may include any suitable hardware, software, components, modules, or objects that facilitate the operations thereof, as well as suitable interfaces for receiving, transmitting, and/or otherwise communicating data or information in a network environment. This may be inclusive of appropriate algorithms and communication protocols that allow for the effective exchange of data or information. Electronic device 100 may include virtual elements.

In regards to the internal structure associated with electronic device 100, electronic device 100 can include memory elements for storing information to be used in the operations outlined herein. Electronic device 100 may keep information in any suitable memory element (e.g., random access memory (RAM), read-only memory (ROM), erasable programmable ROM (EPROM), electrically erasable programmable ROM (EEPROM), application specific integrated circuit (ASIC), etc.), software, hardware, firmware, or in any other suitable component, device, element, or object where appropriate and based on particular needs. Any of the memory items discussed herein should be construed as being encompassed within the broad term ‘memory element.’ Moreover, the information being used, tracked, sent, or received in electronic device 100 could be provided in any database, register, queue, table, cache, control list, or other storage structure, all of which can be referenced at any suitable timeframe. Any such storage options may also be included within the broad term ‘memory element’ as used herein.

In certain example implementations, functions may be implemented by logic encoded in one or more tangible media (e.g., embedded logic provided in an ASIC, digital signal processor (DSP) instructions, software (potentially inclusive of object code and source code) to be executed by a processor, or other similar machine, etc.), which may be inclusive of non-transitory computer-readable media. In some of these instances, memory elements can store data used for the operations. This includes the memory elements being able to store software, logic, code, or processor instructions that are executed to carry out activities.

In an example implementation, elements of electronic device 100 may include software modules to achieve, or to foster, operations. These modules may be suitably combined in any appropriate manner, which may be based on particular configuration and/or provisioning needs. In example embodiments, such operations may be carried out by hardware, implemented externally to these elements, or included in some other network device to achieve the intended functionality. Furthermore, the modules can be implemented as software, hardware, firmware, or any suitable combination thereof. These elements may also include software (or reciprocating software) that can coordinate with other network elements in order to achieve operations.

Additionally, electronic device 100 may include one or more processors that can execute software or an algorithm to perform activities. A processor can execute any type of instructions associated with the data to achieve operations. In one example, the processors could transform an element or an article (e.g., data) from one state or thing to another state or thing. In another example, the activities may be implemented with fixed logic or programmable logic (e.g., software/computer instructions executed by a processor) and the elements identified herein could be some type of a programmable processor, programmable digital logic (e.g., a field programmable gate array (FPGA), an erasable programmable read-only memory (EPROM), an electrically erasable programmable read-only memory (EEPROM)) or an ASIC that includes digital logic, software, code, electronic instructions, or any suitable combination thereof. Any of the potential processing elements, modules, and machines described herein should be construed as being encompassed within the broad term ‘processor.’

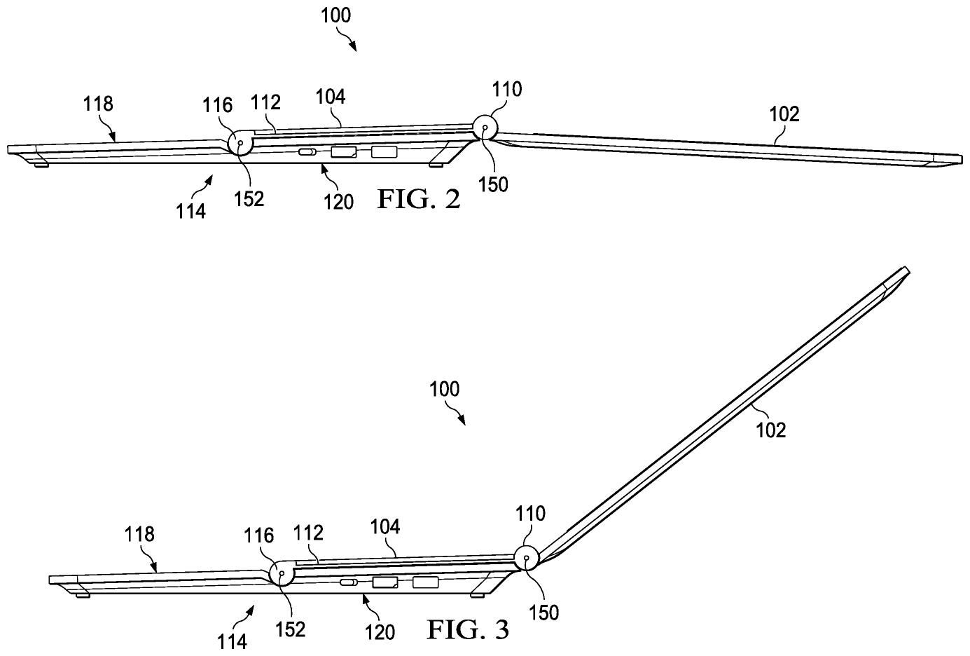

Turning to FIG. 2, FIG. 2 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270° relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120 In an example, carrier plate 112 can be rotated on second hinge 116 about one hundred and eighty degrees (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152.

As illustrated in FIG. 2, carrier plate 112 can be rotated on second hinge 116 so it is over base housing 114. Second housing 104 can be rotated on first hinge 110 such that it is over carrier plate 112. First housing 102 can be rotated on first hinge 110 such that it is in relatively the same plane as second housing, carrier plate 112, and base housing 114. In an example, first housing 102 can be rotated on first hinge 110 about one hundred and eighty degrees (180°) relative to base housing 114. In another example, first housing 102 can be rotated on first hinge 110 about three hundred and sixty degrees (360°) relative to base housing 114. In yet other examples, first housing 102 can be rotated on first hinge 110 about two hundred and seventy degrees (270°) relative to base housing 114 or some other angle, depending on design constraints.

Turning to FIG. 3, FIG. 3 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 3, first housing 102 can be rotated on first hinge 110 from the configuration illustrated in FIG. 2, towards second housing 104, carrier plate 112, and base housing 114. In this configuration, electronic device 100 is in a configuration that is similar to a laptop configuration. In an example, first housing 102 can be rotated on first hinge 110 about one hundred and eighty degrees)(180° relative to base housing 114. In another example, first housing 102 can be rotated on first hinge 110 about three hundred and sixty degrees (360°) relative to base housing 114. In yet other examples, first housing 102 can be rotated on first hinge 110 about two hundred and seventy degrees (270°) relative to base housing 114 or some other angle, depending on design constraints.

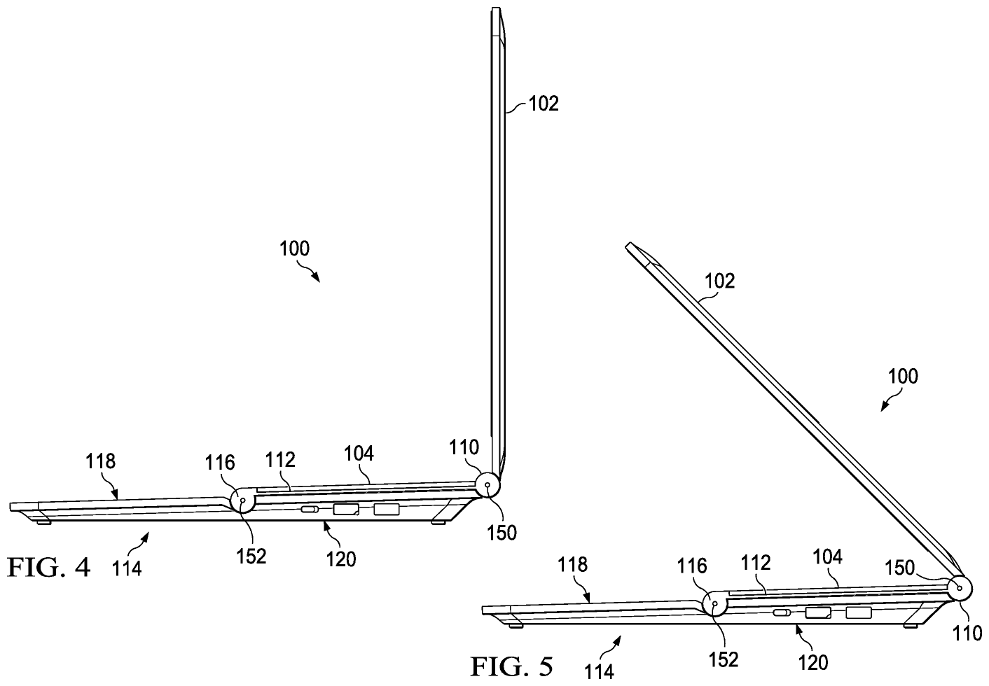

Turning to FIG. 4, FIG. 4 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110 In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270°) relative to first housing 102 or some other angle, depending on design constraints.

Carrier plate 112 can also be rotatably coupled to first hinge 110 In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 4, first housing 102 can be rotated on first hinge 110 from the configuration illustrated in FIG. 3, towards second housing 104, carrier plate 112, and base housing 114. In this configuration, electronic device 100 is in a configuration where first housing 102 is about perpendicular to second housing 104, carrier plate 112, and base housing 114. In an example, first housing 102 can be rotated on first hinge 110 about one hundred and eighty degrees (180°) relative to base housing 114. In another example, first housing 102 can be rotated on first hinge 110 about three hundred and sixty degrees (360°) relative to base housing 114. In yet other examples, first housing 102 can be rotated on first hinge 110 about two hundred and seventy degrees (270°) relative to base housing 114 or some other angle, depending on design constraints.

Turning to FIG. 5, FIG. 5 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 5, first housing 102 can be rotated on first hinge 110 from the configuration illustrated in FIG. 4, towards second housing, carrier plate 112, and base housing 114. In this configuration, electronic device 100 is in a configuration that is similar to a semi-closed laptop configuration. In an example, first housing 102 can be rotated on first hinge 110 about one hundred and eighty degrees (180°) relative to base housing 114. In another example, first housing 102 can be rotated on first hinge 110 about three hundred and sixty degrees (360°) relative to base housing 114. In yet other examples, first housing 102 can be rotated on first hinge 110 about two hundred and seventy degrees (270°) relative to base housing 114 or some other angle, depending on design constraints.

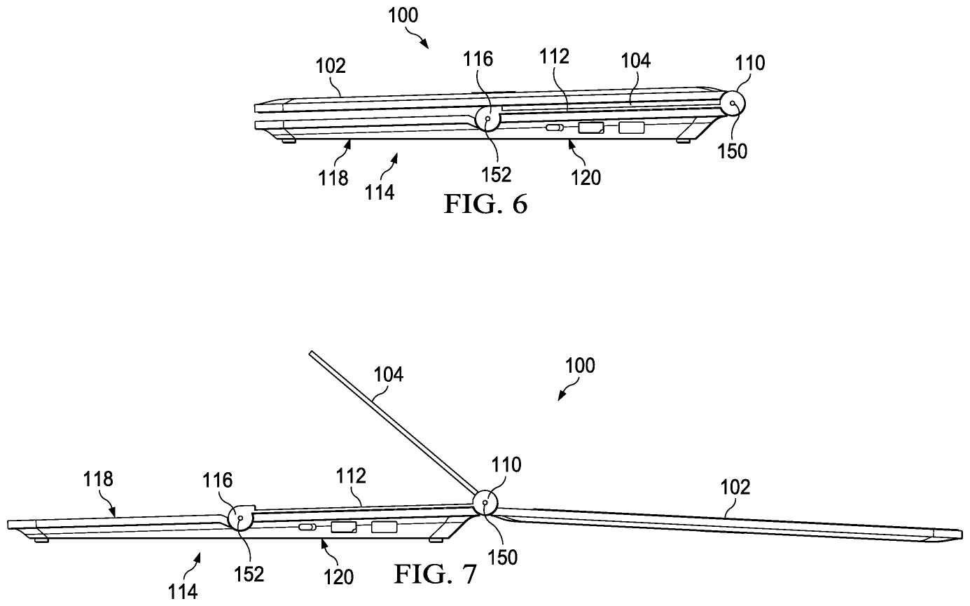

Turning to FIG. 6, FIG. 6 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180° relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 6, first housing 102 can be rotated on first hinge 110 from the configuration illustrated in FIG. 5, towards second housing 104, carrier plate 112, and base housing 114. In this configuration, electronic device 100 is in a configuration that is similar to a closed laptop configuration. In an example, first housing 102 can be rotated on first hinge 110 about one hundred and eighty degrees (180°) relative to base housing 114. In another example, first housing 102 can be rotated on first hinge 110 about three hundred and sixty degrees (360°) relative to base housing 114. In yet other examples, first housing 102 can be rotated on first hinge 110 about two hundred and seventy degrees (270°) relative to base housing 114 or some other angle, depending on design constraints.

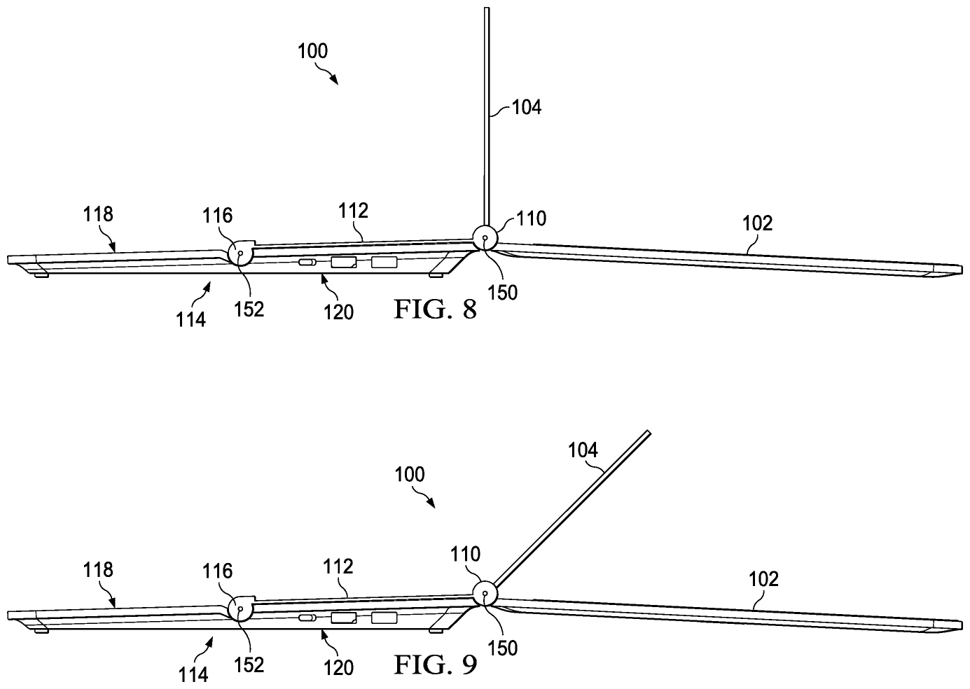

Turning to FIG. 7, FIG. 7 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees(360°) relative to first housing 102. In yet other examples, second housing 104 can be rotated on first hinge 110 about two hundred and seventy degrees) (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 7, second housing 104 can be rotated on first hinge 110 from the configuration illustrated in FIG. 2, towards first housing 102 and away from carrier plate 112 and base housing 114.

Turning to FIG. 8, FIG. 8 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 8, second housing 104 can be rotated on first hinge 110 from the configuration illustrated in FIG. 7, towards first housing 102 and away from carrier plate 112 and base housing 114. In this configuration, electronic device 100 is in a configuration where second housing 104 is about perpendicular to first housing 102, carrier plate 112, and base housing 114.

Turning to FIG. 9, FIG. 9 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 9, second housing 104 can be rotated on first hinge 110 from the configuration illustrated in FIG. 8, towards first housing 102 and away from carrier plate 112 and base housing 114.

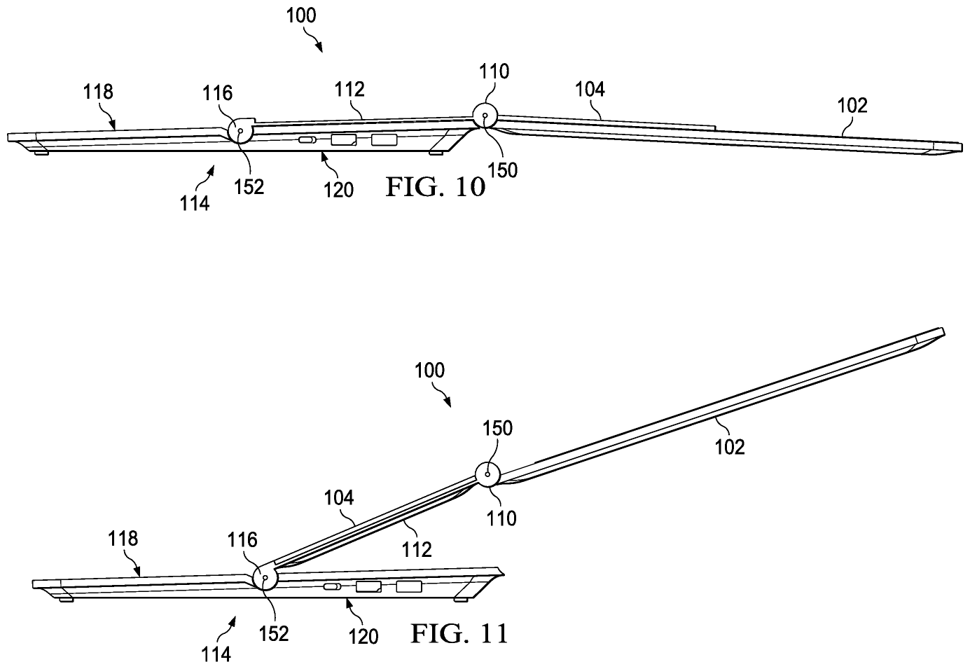

Turning to FIG. 10, FIG. 10 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees)(180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 10, second housing 104 can be rotated on first hinge 110 from the configuration illustrated in FIG. 9, towards first housing 102 and away from carrier plate 112 and base housing 114. In this configuration, second housing 104 can be over or on first housing 102.

Turning to FIG. 11, FIG. 11 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270° relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 11, carrier plate 112 can be rotated on second hinge 116 from the configuration illustrated in FIG. 2 away from second base housing portion 120 in base housing 114.

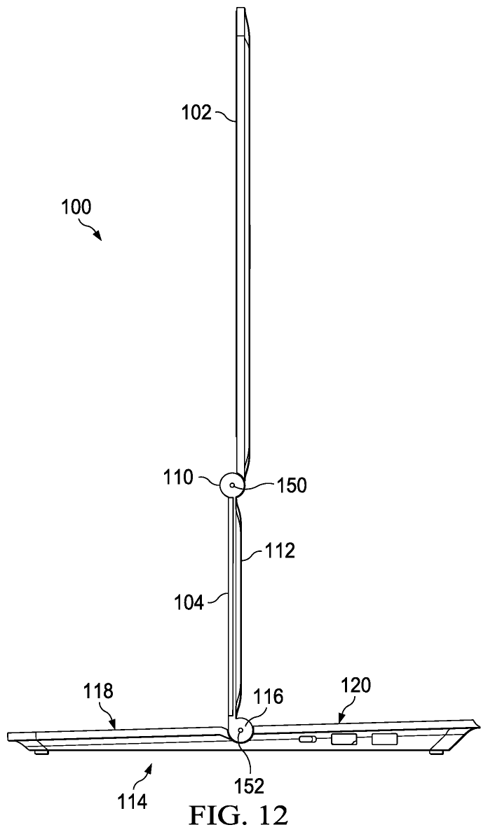

Turning to FIG. 12, FIG. 12 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270° relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 12, carrier plate 112 can be rotated on second hinge 116 from the configuration illustrated in FIG. 11 away from second base housing portion 120 in base housing 114. In this configuration, electronic device 100 is in a configuration where first housing 102, second housing 104, and carrier plate 112 are about perpendicular to base housing 114.

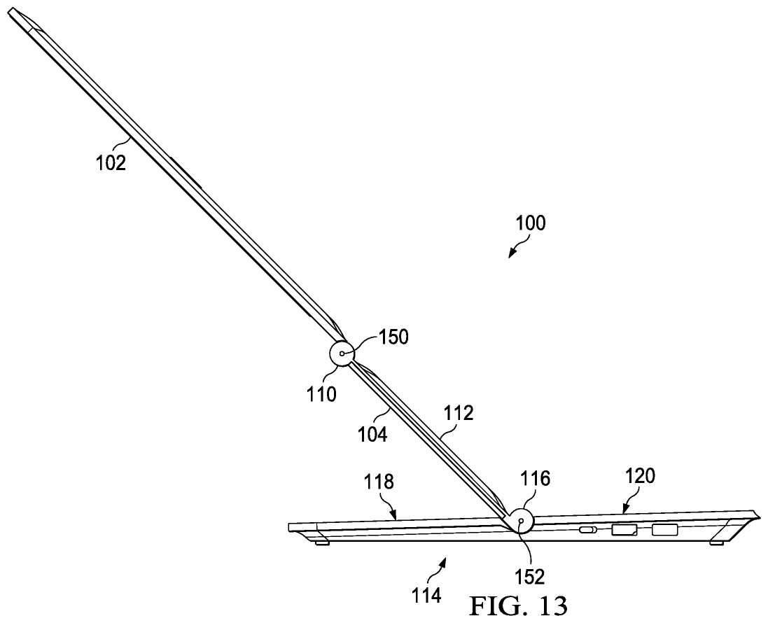

Turning to FIG. 13, FIG. 13 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 13, carrier plate 112 can be rotated on second hinge 116 from the configuration illustrated in FIG. 12, towards first base housing portion 118 and away from second base housing portion 120 in base housing 114.

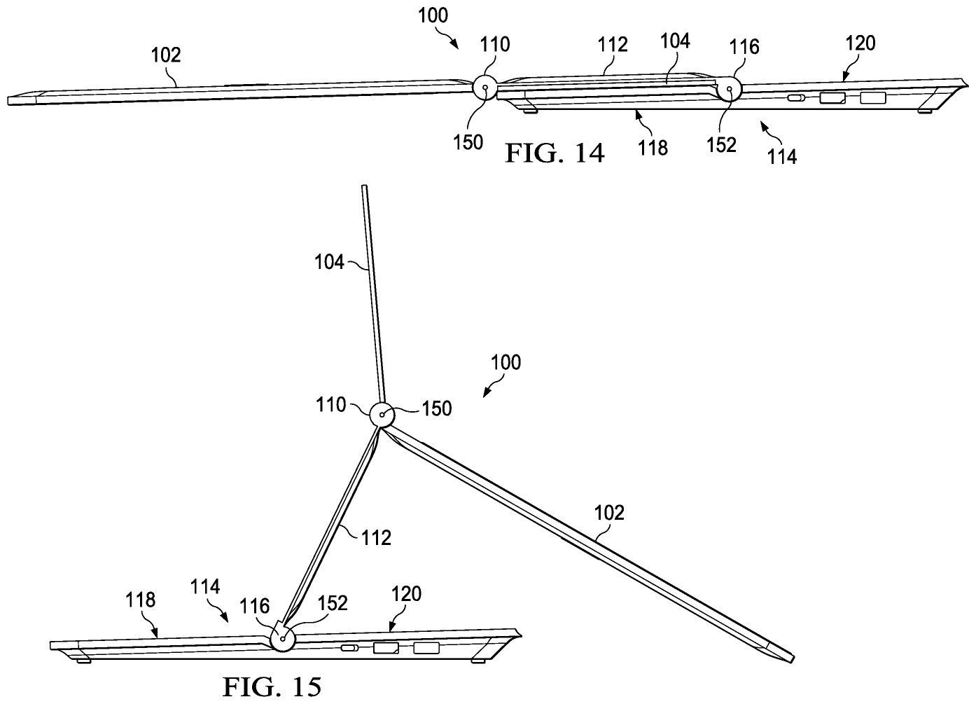

Turning to FIG. 14, FIG. 14 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152. As illustrated in FIG. 14, carrier plate 112 can be rotated on second hinge 116 from the configuration illustrated in FIG. 13, towards first base housing portion 118 and away from second base housing portion 120 in base housing 114.

Turning to FIG. 15, FIG. 15 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152.

As illustrated in FIG. 15, first housing 102 can be rotated on first hinge 110, second housing 104 can be rotated on first hinge 110, and carrier plate can be rotated on second hinge 116 to a configuration where a user can view first housing display 106 in first housing 102 and second housing display 108 in second housing 104. More specifically, carrier plate 112 can be rotated on second hinge 116 from the configuration illustrated in FIG. 2 to a position away from second base housing portion 120 in base housing 114 (e.g., similar to the position of carrier plate 112 illustrated in FIG. 11). First housing 102 and second housing 104 can each be independently rotated on first hinge 110 to a desired viewing angle of the user.

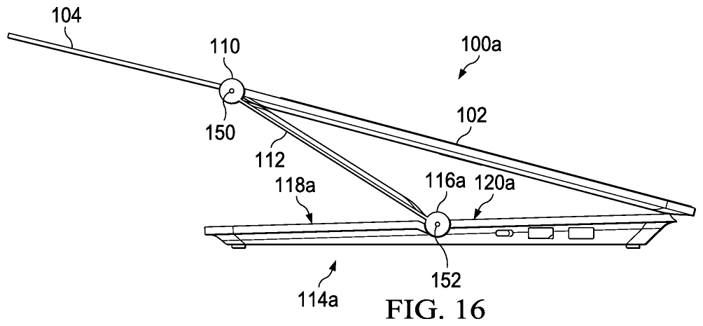

Turning to FIG. 16, FIG. 16 is a simplified block diagram of an electronic device 100a configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees) (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. Base housing 114 can include first base housing portion 118 and second base housing portion 120. In an example, carrier plate 112 can be rotated on second hinge 116 about one hundred and eighty degrees) (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. First hinge 110 can include first hinge retention mechanism 150. Second hinge 116 can include second hinge retention mechanism 152.

As illustrated in FIG. 16, first housing 102 can be rotated on first hinge 110, second housing 104 can be rotated on first hinge 110, and carrier plate can be rotated on second hinge 116 to a configuration where a user can view first housing display 106 in first housing 102 and second housing display 108 in second housing 104. More specifically, carrier plate 112 can be rotated on second hinge 116 towards first base housing portion 118 and away from second base housing portion 120 in base housing 114 (e.g., similar to the position of carrier plate 112 illustrated in FIG. 13). First housing 102 and second housing 104 can each be independently rotated on first hinge 110 to a desired viewing angle of the user.

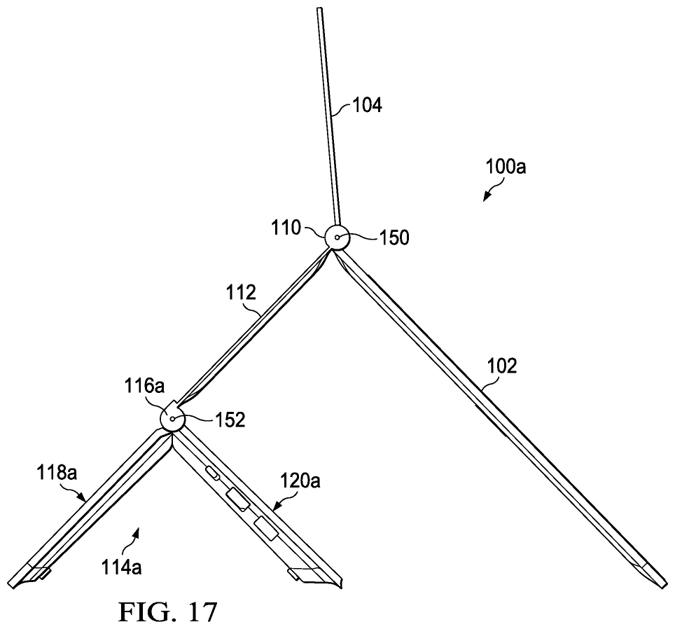

Turning to FIG. 17, FIG. 17 is a simplified block diagram of an electronic device 100a configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees) (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to a second hinge 116a. A base housing 114a can be rotatably coupled to carrier plate 112 using second hinge 116a. Base housing 114a can include a first base housing portion 118a and a second base housing portion 120a. In an example, first base housing portion 118a and second base housing portion 120a can be rotated on second hinge 116a. More specifically, as illustrated in FIG. 17, first base housing portion 118a and second base housing portion 120a can be rotated towards each other on second hinge 116a to create a tent like configuration.

In an example, first base housing portion 118a can be rotated on second hinge 116a about forty-five degrees (45°) relative to carrier plate 112. In another example, first base housing portion 118a can be rotated on second hinge 116a about ninety degrees (90°) relative to carrier plate 112. In another example, first base housing portion 118a can be rotated on second hinge 116a about one hundred and eighty degrees (180°) relative to carrier plate 112. In yet another example, first base housing portion 118a can be rotated on second hinge 116a about three hundred and sixty degrees (360°) relative to carrier plate 112. In yet other examples, first base housing portion 118a can be rotated on second hinge 116a about two hundred and seventy degrees (270°) relative to carrier plate 112 or some other angle, depending on design constraints.

In an example, second base housing portion 120a can be rotated on second hinge 116a about forty-five degrees (45°) relative to carrier plate 112. In another example, second base housing portion 120a can be rotated on second hinge 116a about ninety degrees (90°) relative to carrier plate 112. In another example, second base housing portion 120a can be rotated on second hinge 116a about one hundred and eighty degrees (180°) relative to carrier plate 112. In another example, second base housing portion 120a can be rotated on second hinge 116a about three hundred and sixty degrees (360°) relative to carrier plate 112. In yet other examples, second base housing portion 120a can be rotated on second hinge 116a about two hundred and seventy degrees (270°) relative to carrier plate 112 or some other angle, depending on design constraints. First hinge 110 can include first hinge retention mechanism 150. Second hinge 116a can include second hinge retention mechanism 152.

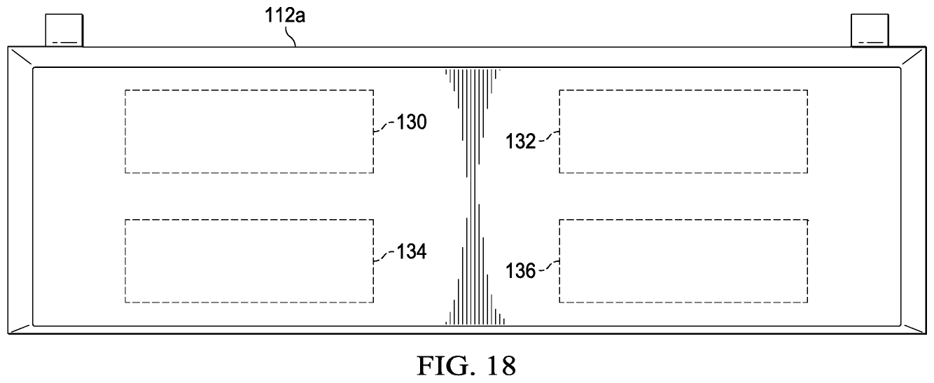

Turning to FIG. 18, FIG. 18 is a simplified block diagram of a portion of an electronic device configured to enable an electronic device with multiple hinges. As illustrated in FIG. 18, a carrier plate 112a can include one or more thermal solutions 130, audio components 132, battery 134, and/or storage compartment 136. Thermal solution 130 can be an active thermal solution (e.g., a fan) and/or a passive thermal solution (e.g., a cold plate) to help cool or reduce the temperature of one or more components of electronic device 100. Battery 134 may be a primary battery and/or secondary battery for electronic device 100. Storage compartment 136 may be an area or compartment where physical things can be stored. More specifically, storage compartment 136 may be an area where a stylus or keyboard can be stored until needed by a user of electronic device 100.

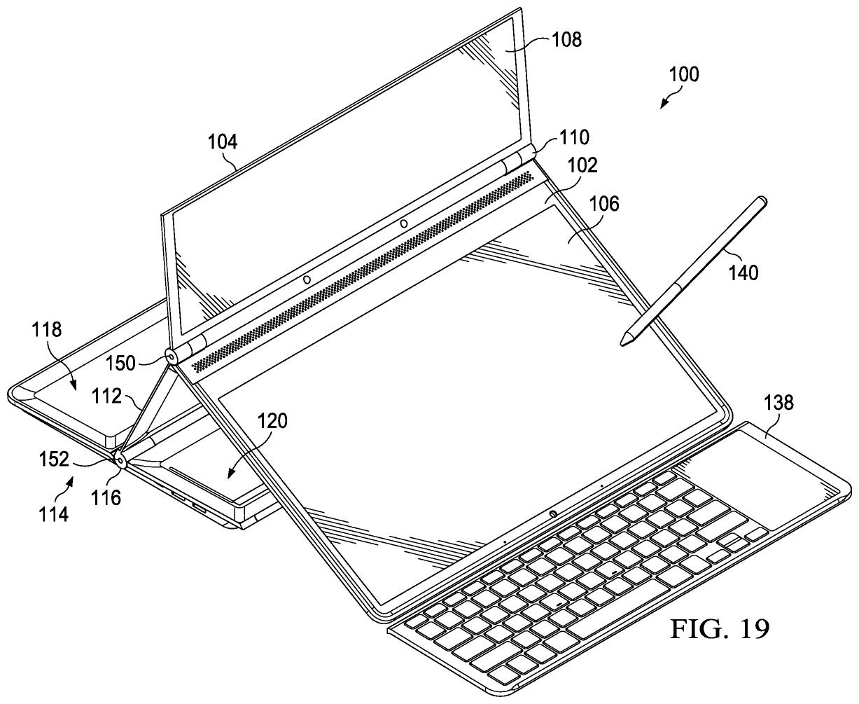

Turning to FIG. 19, FIG. 19 is a simplified block diagram of an electronic device 100 configured to enable an electronic device with multiple hinges. Electronic device 100 can include first housing 102 and second housing 104. First housing 102 can include first housing display 106 and second housing 104 can include second housing display 108. First housing can be rotatably coupled to second housing 104 using first hinge 110. In an example, second housing 104 can be rotated on first hinge 110 about one hundred and eighty degrees (180°) relative to first housing 102. In another example, second housing 104 can be rotated on first hinge 110 about three hundred and sixty degrees (360°) relative to first housing 102. In yet other examples, second housing 104 can be rotated on first hinge 110 about two hundred and seventy degrees) (270°) relative to first housing 102 or some other angle, depending on design constraints.

Carrier plate 112 can also be rotatably coupled to first hinge 110. In an example, carrier plate 112 can be rotated on first hinge 110 about one hundred and eighty degrees (180°) relative to first housing 102. In another example, carrier plate 112 can be rotated on first hinge 110 about three hundred and sixty degrees (360°) relative to first housing 102. In yet other examples, carrier plate 112 can be rotated on first hinge 110 about two hundred and seventy degrees (270°) relative to first housing 102 or some other angle, depending on design constraints.

Carrier plate 112 can also be rotatably coupled to second hinge 116. Base housing 114 can be rotatably coupled to carrier plate 112 using second hinge 116. In an example, carrier plate 112 can be rotated on second hinge 116 about one hundred and eighty degrees (180°) relative to base housing 114. In another example, carrier plate 112 can be rotated on second hinge 116 about three hundred and sixty degrees (360°) relative to base housing 114. In yet other examples, carrier plate 112 can be rotated on second hinge 116 about two hundred and seventy degrees (270°) relative to base housing 114 or some other angle, depending on design constraints. Base housing 114 can include first base housing portion 118 and second base housing portion 120.

As illustrated in FIG. 19, a keyboard 138 and/or stylus 140 can be in communication with electronic device. Keyboard 138 can be a keyboard, keypad, touchscreen input device, touch pad, or some other input device that allows a user to interact with electronic device and content on a display (e.g., navigate user interface elements, etc.). Keyboard 138 can be coupled to electronic device 100 though a wired (e.g., USB, etc.) or wireless (e.g., Bluetooth, etc.) connection. If first housing display 106 and/or second housing display 108 are a touchscreen or otherwise response to an input tool, stylus 140 can be used as an input device by the user to interact with electronic device and content on display (e.g., navigate interface elements, send messages, etc.).

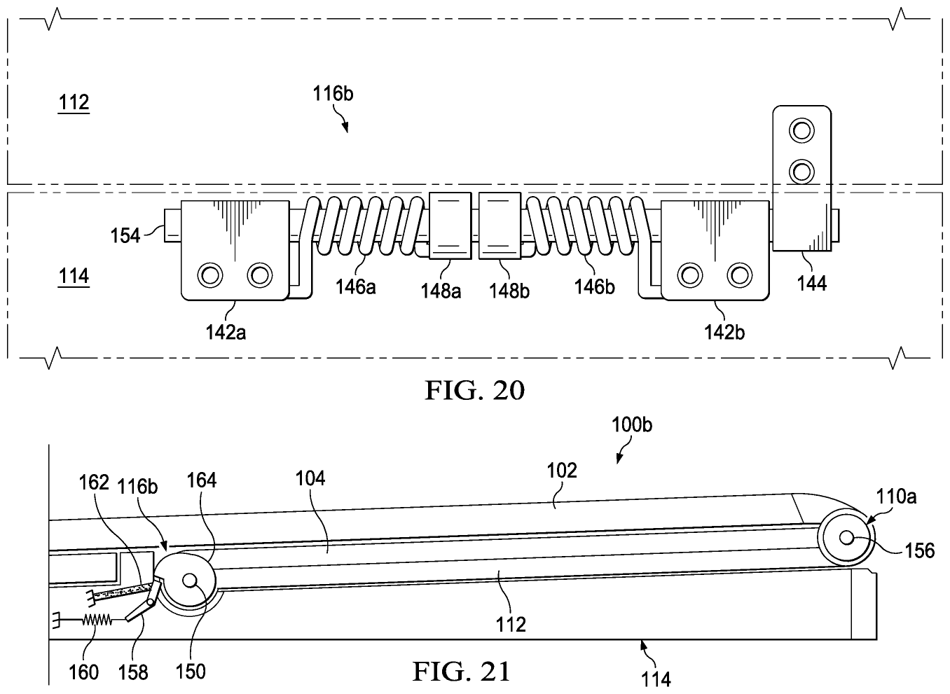

Turning to FIG. 20, FIG. 20 is a simplified block diagram of a portion of an electronic device configured to enable an electronic device with multiple hinges. As illustrated in FIG. 20, a second hinge 116b can include a first mounting bracket 142a, a second mounting bracket 142b, a rotating bracket 144, torsion springs 146a and 146b, a first cam loader 148a, and a second cam loader 148b. First mounting bracket 142a and second mounting bracket 142b can be coupled to base housing 114. Rotating bracket 144 can be coupled to carrier plate 112. A shaft 154 can extend from first mounting bracket 142a, through second mounting bracket 142b, and to rotating bracket 144. Torsion spring 146a can help provide torsion when carrier plate 112 is rotated between about ninety degrees (90°) to about one-hundred and eighty degrees (180°) relative to base housing 114. Torsion spring 146b can help provide torsion when carrier plate 112 is rotated between about to zero degrees (0°) to about ninety degrees (90°) relative to base housing 114. In an illustrative example, torsion spring 146a is configured to provide torque in an opposition direction of torsion spring 146a. First cam loader 148a is configured to engage with shaft 154 when carrier plate 112 is rotated to an angle at or above about ninety degrees (90°) relative to base housing 114. Second cam loader 148b is configured to engage with shaft 154 when carrier plate 112 is rotated less than an angle at or below about ninety degrees (90°) relative to base housing 114. When the angle of rotation of carrier plate 112 is below about ninety degrees (90°), first cam loader 148a does not engage shaft 154 and when the angle of rotation of carrier plate 112 is above about ninety degrees (90°), second cam loader 148b does not engage shaft 154.

In an illustrative example, when a user rotates carrier plate 112 between about to zero degrees (0°) to about ninety degrees(90°) relative to base housing 114, torsion spring 146b assists the user by unwinding and the torque offer by torsion spring 146b is reduced based on the angular position of carrier plate 112 relative to base housing 114. The torque offered by torsion spring 146b reduces because it is configured in such a way that a winding direction of torsion spring 146b is opposite to the direction of movement of carrier plate 112 when the user rotates carrier plate 112 between about to zero degrees (0°) to about ninety degrees (90°) relative to base housing 114. When carrier plate 112 has been rotated to about ninety degrees) (90°) relative to base housing 114, second cam loader 148b disengages with shaft 154 and torsion spring 146b.

When the user rotates carrier plate 112 between about ninety degrees (90°) to about one-hundred and eighty degrees (180°) relative to base housing 114, first cam loader 148a engages with shaft 154 and torsion spring 146a. Torsion spring 146a starts winding and the torque offered by torsion spring 146a increases with respect to the angular position of carrier plate 112 relative to base housing 114. Due to shift in the center of gravity of the electronic device when carrier plate 112 has been rotated above about ninety degrees (90°) relative to base housing, the increase in torque helps to hold carrier plate 112 in a position. The torque offered by torsion spring 146a increases because it is configured in such a way that a winding direction of torsion spring 146a is same as that of the direction of movement of carrier plate 112 when carrier plate 112 is rotated between about ninety degrees (90°) to about one-hundred and eighty degrees (180°) relative to base housing 114.

Turning to FIG. 21, FIG. 21 is a simplified block diagram of a portion of an electronic device 100b configured to enable an electronic device with multiple hinges. As illustrated in FIG. 21, electronic device 100a can include first housing 102, second housing 104, a first hinge 110a, carrier plate 112, base housing 114, and second hinge 116b. First hinge 110a can include an angle position sensor 156. Angle position sensor 156 may be a piezoelectric sensor, a hall effect sensor, or some other type of senor that can be used to detect when first housing has been rotated beyond about ninety degrees (90°) relative to base housing 114. Base housing 114 can include a pawl 158, a tension spring 160, and a pawl controller 162. Second hinge 116b can include a stopper cam 164.

In an illustrative example, when first housing has been rotated less than about ninety degrees (90°) relative to base housing 114 tension spring 160 causes pawl 158 to engage with stopper cam 164 and help keep second housing 104 from rotating on second hinge 116 relative to base housing 114. When first housing has been rotated beyond about ninety degrees) (90°) relative to base housing 114, angle position sensor 156 can be configured to send a signal to pawl controller 162 to unlock or release pawl from stopper cam 164. In some embodiments, pawl 158 and stopper cam 164 are needed to help keep torsion spring 146b (illustrated in FIG. 20) from self lifting or self rotating (i.e., without user input) second housing 104 away from base housing 114 when first housing 102 is closed or rotated less than about ninety degrees (90°) relative to base housing 114. When first housing 102 is rotated beyond about ninety degrees) (90°) relative to base housing 114, the center of gravity of electronic device 100b shifts and the shift in the center of gravity is enough to keep torsion spring 146b (illustrated in FIG. 20) from self lifting or self rotating (i.e., without user input) second housing 104 on second hinge 116 relative to base housing 114.

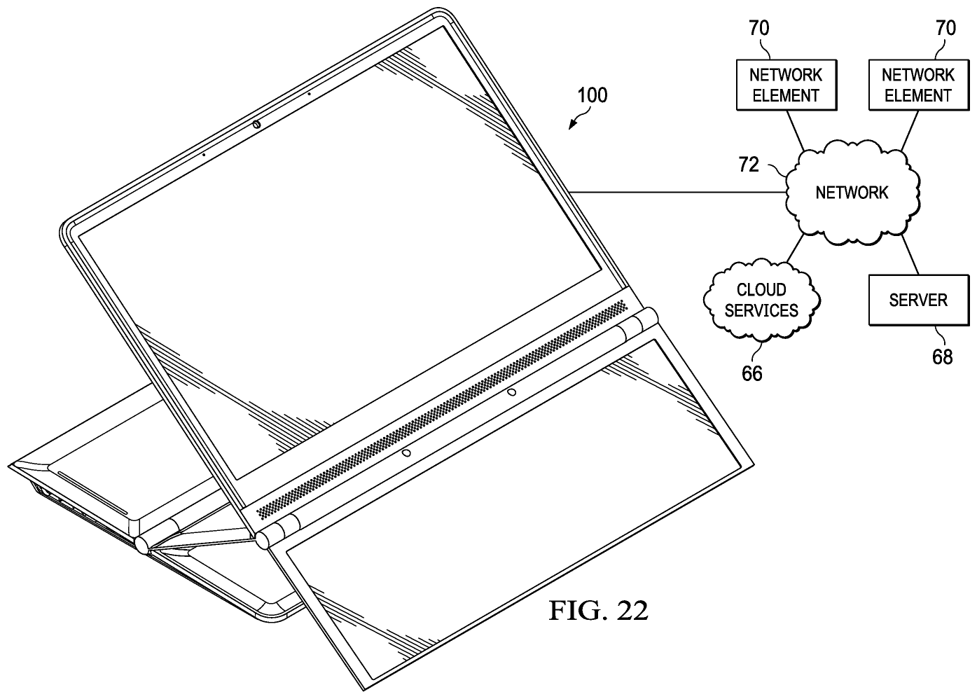

Turning to FIG. 22, FIG. 22 is a simplified block diagram of electronic device 100 configured to enable an electronic device with multiple hinges. In an example, electronic device 100 may be a laptop, a dual screen laptop, a gaming device, or any other device with multiple hinges. Electronic device 100 may be in communication with other electronic devices (not shown), cloud services 166, server 168, and/or one or more network elements 170 using network 172. In some examples, electronic device 100 may be standalone devices and not connected to network 172 or another device.

Elements of FIG. 22 may be coupled to one another through one or more interfaces employing any suitable connections (wired or wireless), which provide viable pathways for network (e.g., network 172, etc.) communications. Additionally, any one or more of these elements of FIG. 22 may be combined or removed from the architecture based on particular configuration needs. Electronic device 100 may include a configuration capable of transmission control protocol/Internet protocol (TCP/IP) communications for the transmission or reception of packets in a network. Electronic device 100 may also operate in conjunction with a user datagram protocol/IP (UDP/IP) or any other suitable protocol where appropriate and based on particular needs.

Turning to the infrastructure of FIG. 22, generally, the system may be implemented in any type or topology of networks. Network 172 represents a series of points or nodes of interconnected communication paths for receiving and transmitting packets of information that propagate through the system. Network 172 offers a communicative interface between nodes, and may be configured as any local area network (LAN), virtual local area network (VLAN), wide area network (WAN), wireless local area network (WLAN), metropolitan area network (MAN), Intranet, Extranet, virtual private network (VPN), and any other appropriate architecture or system that facilitates communications in a network environment, or any suitable combination thereof, including wired and/or wireless communication.

In the system, network traffic, which is inclusive of packets, frames, signals, data, etc., can be sent and received according to any suitable communication messaging protocols. Suitable communication messaging protocols can include a multi-layered scheme such as Open Systems Interconnection (OSI) model, or any derivations or variants thereof (e.g., Transmission Control Protocol/Internet Protocol (TCP/IP), user datagram protocol/IP (UDP/IP)). Messages through the network could be made in accordance with various network protocols, (e.g., Ethernet, Infiniband, OmniPath, etc.). Additionally, radio signal communications over a cellular network may also be provided in the system. Suitable interfaces and infrastructure may be provided to enable communication with the cellular network.

The term “packet” as used herein, refers to a unit of data that can be routed between a source node and a destination node on a packet switched network. A packet includes a source network address and a destination network address. These network addresses can be Internet Protocol (IP) addresses in a TCP/IP messaging protocol. The term “data” as used herein, refers to any type of binary, numeric, voice, video, textual, or script data, or any type of source or object code, or any other suitable information in any appropriate format that may be communicated from one point to another in electronic devices and/or networks. The data may help determine a status of a network element or network. Additionally, messages, requests, responses, and queries are forms of network traffic, and therefore, may comprise packets, frames, signals, data, etc.

It is also important to note that the operations herein illustrate only some of the possible configurations and arrangements that may be executed by, or within, electronic device 100. Some of these configurations and arrangements may be modified or changed considerably without departing from the scope of the present disclosure. Substantial flexibility is provided by electronic device 100 in that any suitable configurations and arrangements may be provided without departing from the teachings of the present disclosure.

Although the present disclosure has been described in detail with reference to particular configurations and arrangements, these example configurations and arrangements may be changed significantly without departing from the scope of the present disclosure. Moreover, certain components may be combined, separated, eliminated, or added based on particular needs and implementations. Additionally, although electronic device 100 has been illustrated with reference to particular elements and operations that facilitate the configurations and arrangements, these elements and operations may be replaced by any suitable architecture, protocols, and/or processes that achieve the intended functionality of electronic device 100.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### OTHER NOTES AND EXAMPLES

Example A1, is an electronic device including a first housing, a second housing, a carrier plate, a first hinge that rotatably couples the first housing to the second housing and the first housing and the second housing to the carrier plate, a base, and a second hinge, where the second hinge rotatably couples the carrier plate to the base.

In Example A2, the subject matter of Example A1 can optionally include a retention mechanism located in the first hinge, where the retention mechanism holds the first housing, the second housing, and the carrier plate in a set position relative to each other.

In Example A3, the subject matter of any one of Examples A1-A2 can optionally include where the first housing includes a first display and the second housing includes a second display.

In Example A4, the subject matter of any one of Examples A1-A3 can optionally include where the first housing can rotate about one hundred and eighty degrees on the first hinge relative to the base.

In Example A5, the subject matter of any one of Examples A1-A4 can optionally include where the second housing can rotate about one hundred and eighty degrees on the first hinge relative to the first housing.

In Example A6, the subject matter of any one of Examples A1-A5 can optionally include where the carrier plate can rotate about one hundred and eighty degrees on the first hinge relative to the first housing.

In Example A7, the subject matter of any one of Examples A1-A6 can optionally include where the carrier plate can rotate about one hundred and eighty degrees on the second hinge relative to the base.

Example M1 is a method including rotating a first housing relative to a second housing, where the first housing is rotatably coupled to the second housing using a first hinge, rotating the second housing relative to a carrier plate, where the second housing is rotatably coupled to the carrier plate using the first hinge, and rotating the carrier plate relative to a base, where the carrier plate is rotatably coupled to the base using a second hinge.

In Example M2, the subject matter of Example M1 can optionally include where the first housing includes a first display and the second housing includes a second display.

In Example M3, the subject matter of any one of the Examples M1-M2 can optionally include where the first housing can rotate about one hundred and eighty degrees on the first hinge.

In Example M4, the subject matter of any one of the Examples M1-M3 can optionally include where the second housing can rotate about one hundred and eighty degrees on the first hinge.

In Example M5, the subject matter of any one of the Examples M1-M4 can optionally include where the carrier plate can rotate about one hundred and eighty degrees on the first hinge.

In Example M6, the subject matter of any one of the Examples M1-M5 can optionally include where the carrier plate can rotate about one hundred and eighty degrees on the second hinge.

Example S1 is a system for enabling an electronic device with multiple hinges. The system can include a first hinge that rotatably couples a first housing to a second housing and a carrier plate to the first housing and to the second housing, where the first hinge includes a first hinge retention mechanism to hold the first housing, the second housing, and the carrier plate in a set display position and a second hinge, where the second hinge rotatably couples the carrier plate to a base, where the second hinge includes a second hinge retention mechanism to hold the carrier plate in a set base position relative to the base.

In Example S2, the subject matter of Example S1 can optionally include where the first hinge retention mechanism is a friction hinge.

In Example S3, the subject matter of any one of the Examples S1-S2 can optionally include where the second hinge retention mechanism is a clutch.

In Example S4, the subject matter of any one of the Examples S1-S3 can optionally include where the first housing can rotate about three hundred and sixty degrees on the first hinge relative to the base.

In Example S5, the subject matter of any one of the Examples S1-S4 can optionally include where the second housing can rotate about three hundred and sixty degrees on the first hinge relative to the first housing.

In Example S6, the subject matter of any one of the Examples S1-S5 can optionally include where the carrier plate can rotate about three hundred and sixty degrees on the first hinge relative to the first housing.

In Example S7, the subject matter of any one of the Examples S1-S6 can optionally include where the carrier plate can rotate about one hundred and eighty degrees on the second hinge relative to the first housing.

What is claimed is:

1. An electronic device comprising:
a first housing;
a second housing;
a carrier plate;
a first hinge that rotatably couples the first housing to the second housing and the first housing and the second housing to the carrier plate;
a base; and
a second hinge, wherein the second hinge rotatably couples the carrier plate to the base.

2. The electronic device of claim 1, further comprising:
a retention mechanism located in the first hinge, wherein the retention mechanism holds the first housing, the second housing, and the carrier plate in a set position relative to each other.

3. The electronic device of claim 1, wherein the first housing includes a first display and the second housing includes a second display.

4. The electronic device of claim 1, wherein the first housing can rotate about one hundred and eighty degrees on the first hinge relative to the base.

5. The electronic device of claim 1, wherein the second housing can rotate about one hundred and eighty degrees on the first hinge relative to the first housing.

6. The electronic device of claim 1, wherein the carrier plate can rotate about one hundred and eighty degrees on the first hinge relative to the first housing.

7. The electronic device of claim 1, wherein the carrier plate can rotate about one hundred and eighty degrees on the second hinge relative to the base.

8. A method comprising:
rotating a first housing relative to a second housing, wherein the first housing is rotatably coupled to the second housing using a first hinge;
rotating the second housing relative to a carrier plate, wherein the second housing is rotatably coupled to the carrier plate using the first hinge; and
rotating the carrier plate relative to a base, wherein the carrier plate is rotatably coupled to the base using a second hinge.

9. The method of claim 8, wherein the first housing includes a first display and the second housing includes a second display.

10. The method of claim 8, wherein the first housing can rotate about one hundred and eighty degrees on the first hinge.

11. The method of claim 8, wherein the second housing can rotate about one hundred and eighty degrees on the first hinge.

12. The method of claim 8, wherein the carrier plate can rotate about one hundred and eighty degrees on the first hinge.

13. The method of claim 8, wherein the carrier plate can rotate about one hundred and eighty degrees on the second hinge.

14. A system for enabling an electronic device with multiple hinges, the system comprising:
a first hinge that rotatably couples a first housing to a second housing and a carrier plate to the first housing and to the second housing, wherein the first hinge includes a first hinge retention mechanism to hold the first housing, the second housing, and the carrier plate in a set display position; and
a second hinge, wherein the second hinge rotatably couples the carrier plate to a base, wherein the second hinge includes a second hinge retention mechanism to hold the carrier plate in a set base position relative to the base.

15. The system of claim 14, wherein the first hinge retention mechanism is a friction hinge.

16. The system of claim 14, wherein the second hinge retention mechanism is a clutch.

17. The system of claim 14, wherein the first housing can rotate about three hundred and sixty degrees on the first hinge relative to the base.

18. The system of claim 17, wherein the second housing can rotate about three hundred and sixty degrees on the first hinge relative to the first housing.

19. The system of claim 18, wherein the carrier plate can rotate about three hundred and sixty degrees on the first hinge relative to the first housing.

20. The system of claim 19, wherein the carrier plate can rotate about one hundred and eighty degrees on the second hinge relative to the first housing.
